(19) United States
(12) Patent Application Publication
(10) Pub. No.: US 2023/0282546 A1
(43) Pub. Date: Sep. 7, 2023

(54) PACKAGING ARCHITECTURE WITH ACTIVE COOLING

(71) Applicants: Bernd Waidhas, Pettendorf (DE); Sonja Koller, Bavaria (DE); Jan Proschwitz, Riesa SN (DE); Eduardo De Mesa, Munich (DE)

(72) Inventors: Bernd Waidhas, Pettendorf (DE); Sonja Koller, Bavaria (DE); Jan Proschwitz, Riesa SN (DE); Eduardo De Mesa, Munich (DE)

(73) Assignee: Intel Corporation, Santa Clara, CA (US)

(21) Appl. No.: 17/685,496

(22) Filed: Mar. 3, 2022

(51) Int. Cl. H01L 23/427; H01L 23/367; H01L 23/08; H01L 23/473; H01L 23/48; H01L 21/768

(52) U.S. Cl. CPC H01L 23/427; H01L 23/3672; H01L 23/08; H01L 23/473; H01L 23/481; H01L 21/76877

(57) ABSTRACT

Embodiments of a microelectronic assembly comprise an integrated circuit (IC) die and a package substrate having a core and redistribution layers on either side of the core. The IC die is coupled to a face of the package substrate, the face being parallel to the core. The core comprises one of glass, ceramic, and metal. The redistribution layers comprise one or more layers of a dielectric material, with conductive traces adjacent to the one or more layers of the dielectric material and conductive vias through the one or more layers of the dielectric material. The core comprises a hollow channel.

### TECHNICAL FIELD

The present disclosure relates to techniques, methods, and apparatus directed to a packaging architecture with active cooling.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a simplified cross-sectional view of an example microelectronic assembly according to some embodiments of the present disclosure.

FIG. 1B is a simplified block diagram illustrating an example operation of a portion of microelectronic assembly of FIG. 1A according to some embodiments.

FIG. 2 is a simplified exploded perspective view of a portion of another example microelectronic assembly according to some embodiments of the present disclosure.

FIG. 3 is a top-view of a portion of an example channel in a microelectronic assembly according to some embodiments of the present disclosure.

FIG. 4 is a top-view of a portion of another example channel in a microelectronic assembly according to some embodiments of the present disclosure.

FIG. 5 is a top-view of a portion of yet another example channel in a microelectronic assembly according to some embodiments of the present disclosure.

FIG. 6 is a top-view of a portion of yet another example channel in a microelectronic assembly according to some embodiments of the present disclosure.

FIG. 7 is a top-view of a portion of yet another example channel in a microelectronic assembly according to some embodiments of the present disclosure.

FIG. 8 is a top-view of a portion of yet another example channel in a microelectronic assembly according to some embodiments of the present disclosure.

FIG. 9 is a top-view of a portion of yet another example channel in a microelectronic assembly according to some embodiments of the present disclosure.

FIG. 10 is a top-view of a portion of yet another example channel in a microelectronic assembly according to some embodiments of the present disclosure.

FIG. 11 is a simplified cross-sectional view of another example microelectronic assembly according to some embodiments of the present disclosure.

FIG. 12 is a simplified cross-sectional view of yet another example microelectronic assembly according to some embodiments of the present disclosure.

FIG. 13 is a simplified cross-sectional view of yet another example microelectronic assembly according to some embodiments of the present disclosure.

FIG. 14 is a simplified cross-sectional view of yet another example microelectronic assembly according to some embodiments of the present disclosure.

FIGS. 15A-15E are simplified cross-sectional views of various stages of manufacture of an example microelectronic assembly according to some embodiments of the present disclosure.

FIG. 16 is a cross-sectional view of a device package that includes one or more microelectronic assemblies in accordance with any of the embodiments disclosed herein.

FIG. 17 is a cross-sectional side view of a device assembly that includes one or more microelectronic assemblies in accordance with any of the embodiments disclosed herein.

FIG. 18 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

A constant challenge in microelectronics is the need for efficient cooling methods. As power consumed by IC dies increases, so does the heat they generate. At the same time, the form factor of microelectronic assemblies including individual packages are constrained by volume, posing fundamental problems in transferring heat from these IC dies effectively. Previous cooling techniques have been based on either passive systems or active systems. Passive systems use bulk materials to conduct heat through substrates microelectronic packages. Historically, the materials chosen for such passive systems include ceramics such as alumina and beryllia, metal alloys such as Kovar Fe/Ni/Co alloy, metal sheets of copper or aluminum, and glass fiber epoxy laminates. However, today's electronic systems often exceed the thermal density and mechanical reliability limits of these materials.

Active systems are typically characterized by forced convection of a coolant (e.g., cooling agent, working fluid), such as air, or a liquid coolant. Fans forcing air to flow around a board or over a metal finned structure in intimate contact with the IC die have been the mainstay of cooling by active systems. Active systems using immersion cooling, spray cooling, and pumped convective cooling in microchannels have been used to a limited extent. The primary difficulty of all the active systems is the requirement for pumping the coolant. Micro heat pipes with channels and wick materials on etched Kovar over IC dies are used in some electronic applications; such micro heat pipes have the advantage of being a passive system with the heat transfer efficiency comparable to active systems. However, such existing solutions tend to focus on intimate proximity to the IC die, with passive or active systems being in direct contact, or in direct conductive path, with an unattached surface of the IC die. Yet, in many microelectronic assemblies, the heat producing region of the IC die is proximate to the surface of the IC die attached to the package substrate or printed circuit board (PCB), making existing active and passive systems inefficient at best for cooling hot regions in the IC die, or package substrate (or PCB). Further, any cooling systems mounted on the IC die adds height to the microelectronic assembly, which may be a problem in electronic systems that require a small form factor.

In this regard, some embodiments of the present disclosure alleviate such problems by providing a microelectronic assembly comprising an IC die and a package substrate (or PCB) comprising a core having a hollow channel, for example, configured to permit flow of a coolant, and redistribution layers on either side of the core. The IC die is coupled to a face of the package substrate, the face being parallel to the core, and the core comprises one of glass, ceramic, and metal. The redistribution layers comprise one or more layers of a dielectric material, with conductive traces and conductive vias therethrough. The channels with the coolant can extract heat from within the package substrate (or PCB), mitigating heat across the package substrate (or PCB), with consequent smaller temperature drops across the package substrate (or PCB). Such package substrate (or PCB) with active cooling enables additional heat path, higher device performance because more heat can be extracted, and slim form factors because of low height profile.

Embodiments also provide for a method of forming a component in a microelectronic assembly, the method comprising: providing a panel of a core material comprising one of glass, ceramic, and metal; forming an open channel in the core material; sealing a topside of the open channel with another panel comprising the core material to complete forming a core with a closed channel therein; forming through-holes in the core through a thickness of the core; depositing a conductive material in the through-holes; forming conductive traces on either side of the core; depositing a dielectric material on the conductive traces on either side of the core; forming conductive vias through the dielectric material to couple to the conductive traces; and repeating forming the conductive traces, depositing the dielectric material, and forming the conductive vias until a desired structure of redistribution layers is obtained on either side of the core.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field effect transistors (FETs), e.g., metal-oxide semiconductor field effect transistors (MOSFETs). In general, a FET is a three-terminal device that includes source, drain, and gate terminals and uses electric field to control current flowing through the device. A FET typically includes a conduit material, a source region and a drain regions provided in and/or over the conduit material, and a gate stack that includes a gate electrode material, alternatively referred to as a “work function” material, provided over a portion of the conduit material (the “conduit portion”) between the source and the drain regions, and optionally, also includes a gate dielectric material between the gate electrode material and the conduit material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

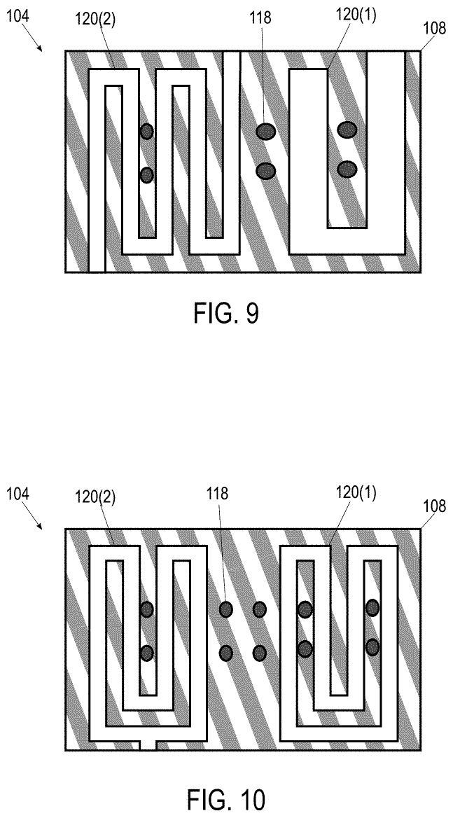

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

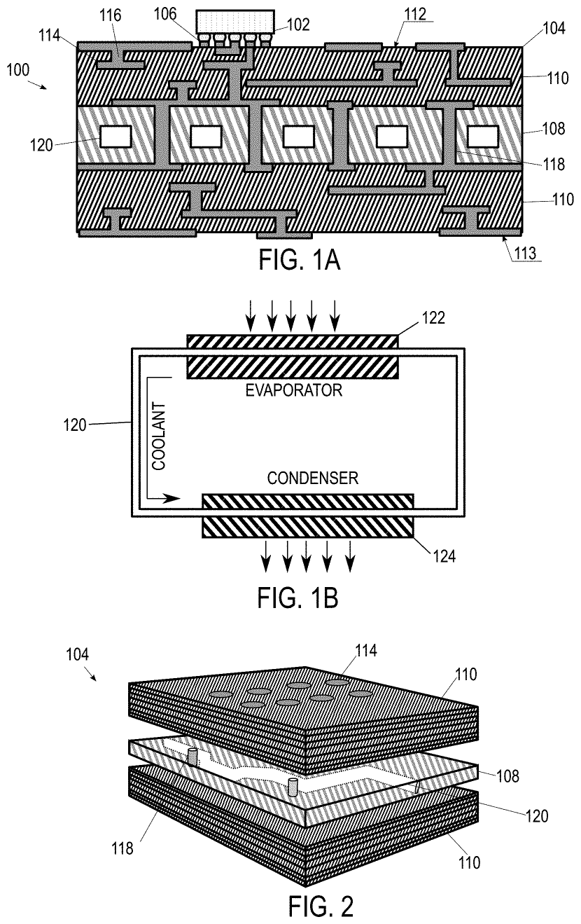

FIG. 1A is a simplified cross-sectional view of a microelectronic assembly 100 according to some embodiments of the present disclosure. Microelectronic assembly 100 comprises an IC die 102 coupled by interconnects 106 to a package substrate 104. In some embodiments, the component labeled as 104 may alternatively be a PCB, and IC die 102 may comprise a packaged IC die or an unpackaged (e.g., bare) IC die. In various embodiments, interconnects 106 may comprise DTPS interconnects. In other embodiments (e.g., where component labeled as 104 comprises a PCB), interconnects 106 may comprise pin grid arrays, land grid arrays, and such package-to-board interconnects coupled by solder. Package substrate 104 comprises a core 108 and redistribution layers 110 on either side of core 108. IC die 102 is coupled to a surface 112 of package substrate 104, surface 112 being parallel to core 108. In some embodiments, package substrate 104 is coupled to a PCB (not shown) on another surface 113 opposite to surface 112.

In various embodiments, core 108 comprises glass; in other embodiments, core 108 comprises ceramic; in yet other embodiments, core 108 comprises metal. Redistribution layers 110 comprise one or more layers of a dielectric material (e.g., organic dielectric material such a prepreg, ABF, polyimide, bismaleimide triazine (BT) resin, etc.), with conductive traces 114 adjacent to the one or more layers of the dielectric material and conductive vias 116 through the one or more layers of the dielectric material. In many embodiments, conductive traces 114 and conductive vias 116 may be fabricated from copper, aluminum, and/or another conductive metal or metal alloy suitable for the structure and known in the art.

Conductive through-holes 118 through core 108 are coupled to conductive traces 114 in redistribution layers 110 on either side of core 108. In embodiments where core 108 comprises metal, conductive through-holes 118 are electrically insulated from each other by suitable means, for example, an appropriate dielectric coating (not shown) around through-holes 118. In various embodiments, core 108 comprises a hollow channel 120 therein configured to permit flow of a coolant. In some embodiments, the coolant may be a liquid; in other embodiments, the coolant may be a gas; in yet other embodiments, the coolant may be in both liquid state and gaseous state, depending on its temperature (e.g., gaseous state at higher temperatures and liquid state at lower temperature) within channel 120.

Turning to the operation of channel 120 in microelectronic assembly 100, FIG. 1B illustrates a simplified block diagram describing the operation of channel 120 as a heat pipe in some embodiments. In a general sense, a heat pipe is a transport mechanism to move heat from a hot source to a region where the heat can be dissipated. Heat pipes distribute heat in plane and can be useful to mitigate hot spots in package substrate 104. They can be combined with heat spreaders which couple to core 108 by direct contact or by one or more thermal vias. As heat is applied to channel 120 at an evaporator 122, the coolant inside channel 120 will absorb the heat and, in some cases, it will change phase from liquid to vapor. The heated coolant moves to a colder section of channel 120, a condenser 124, where it transfers the heat and cools down, and in some cases, it condenses back into liquid form. The heating and cooling and, in some cases, the evaporation and condensation, of the coolant forms a pumping action to move the coolant and thus the heat along channel 120. In other embodiments, an external pump or other pressure regulator may maintain a constant flow of the coolant inside channel 120. In yet other embodiments, natural convection may be sufficient to move the coolant inside channel 120.

In many embodiments, evaporator 122 may comprise a region in core 108 underneath (or in a shadow of) IC die 102. IC die 102 may generate heat during operation; the heat may reach core 108 by conduction through redistribution layer 110. This localized region in package substrate 104 may be hotter than surrounding regions in package substrate 104 and may function as evaporator 122. Condenser 124 may comprise a region of channel 120 distant from evaporator 122. In some embodiments, condenser 124 may be a heat sink; in other embodiments, condenser 124 may be coupled to or in direct contact with a heat sink; in yet other embodiments, condenser 124 may be a connection to an external cooling circuit; in yet other embodiments, condenser 124 may be an external device that is part of an external cooling circuit.

In many embodiments, channel 120 comprises a part of a heat pipe in a suitable heat transfer configuration, such as a standard heat pipe (SHP), a loop heat pipe (LHP), a fork-end heat pipe (FEHP), a micro heat pipe (MHP), and a pulsating heat pipe (PHP). Various other heat pipe configurations may also be encompassed within the broad scope of the embodiments. In a general sense, the SHP typically comprises a coolant in liquid form that evaporates under heat at evaporator 122 to a vapor phase. In such embodiments, channel 120 may comprise a wick or other structure for transporting the coolant in its liquid form through capillary action. The coolant in such embodiments may be water or another fluid compatible with microelectronic assemblies. The coolant may circulate in an open loop or closed loop through evaporator 122.

In LHPs, the coolant circulates in a closed loop between evaporator 122, and condenser 124. In a FEHP, a portion of channel 120 proximate to condenser 124 may comprise several forks or loops whereas another portion of channel 120 proximate to evaporator 122 may comprise a single channel. In MHPs, a mean curvature of the liquid-vapor interface of the coolant is comparable in magnitude to the reciprocal of the hydraulic radius of channel 120. Typically, channel 120 in MHPs have convex but cusped cross sections (e.g., a polygon), with a hydraulic diameter in the range of 10-500 micrometers. In PHPs, channel 120 is of capillary dimensions and shaped in a meandering (e.g., snaking) pathway with multiple turns (e.g., U-turns) with no additional capillary structure (e.g., wick) inside. In such embodiments, channel 120 may be in an open loop (e.g., coupled to an external cooling circuit) or a closed loop, in which it is joined end to end within package substrate 104.

In other embodiments, depending on the core thickness and package substrate size, channels 120 shaped as straight, open pathways oriented along the direction of any forced or natural convection can serve as air tunnels for cooling, or as micro-channel heat sinks for immersion cooling.

Turning back to FIG. 1A, in some embodiments, core 108 comprises a plurality of channels 120. In some such embodiments, some channels in the plurality of channels are not coplanar with other channels. In other embodiments, portions of channel 120 may not be coplanar with other portions of channel 120. In some embodiments, channel 120 may have a rectangular cross-section (e.g., as shown). In other embodiments, channel 120 may have a circular cross-section. In yet other embodiments, channel 120 may have a triangular cross-section. In yet other embodiments, channel 120 may have an irregularly shaped cross-section. Channel 120 may have any suitable cross-sectional shape within the broad scope of the embodiments. In some embodiments, channel 120 may be shaped with a plurality of turns in a plane parallel to surface 112 (or core 108) of package substrate 104. In some embodiments, channel 120 is joined end to end within package substrate 104, to form a closed loop. In some embodiments, the loops may not be uniformly spaced apart, so that a portion of channel 120 may be looped closer together than another portion. In one example embodiment, portion of channel 120 may be spaced 60 micrometers apart from another portion. In embodiments with more than one channel 120, the channels may be spaced apart from each other by 60 micrometers in some embodiments.

In some embodiments, more than one IC die 102 may be coupled to surface 112 of package substrate 104 and one IC die 102 may produce more heat during operation than another IC die 102. In such embodiments, a portion of channel 120 proximate to the IC die producing more heat may be more densely packed with a greater number of turns than another portion of the channel proximate to the cooler IC die. In some embodiments, channel 120 may be sealed within package substrate 104, without any turns. In some embodiments, a portion of channel 120 may cross another portion in a plane parallel to surface 112. In some embodiments, channel 120 may comprise forked portions in a plane parallel to surface 112. In some embodiments, channel 120 may be 60 micrometers in width (e.g., measured along a dimension parallel to surface 112 or core 108) and up to 500 micrometers in height (e.g., measured along a dimension parallel to a thickness of core 108). The height of channel 120 may be typically less than the thickness of core 108, so that channel 120 is entirely embedded in core 108. In some embodiments, a portion of channel 120 may be wider than another portion.

In some embodiments, channel 120 may be coupled to an external cooling circuit. In a particular embodiment, the external cooling circuit may be active, for example, forcing the coolant through channel 120. In another embodiment, the external coolant may be passive, for example, comprising a heat sink that is coupled to channel 120 by thermal vias. In some embodiments, the external cooling circuit is removably (alternatively, permanently) affixed to package substrate 104 on surface 113 opposite to surface 112, or on surface 112 itself. In some other embodiments, the external cooling circuit is removably (alternatively, permanently) affixed to package substrate 104 on a face orthogonal to surface 112.

FIG. 2 is a simplified exploded perspective view of a portion of another example microelectronic assembly according to some embodiments of the present disclosure. Redistribution layers 110 in package substrate 104 may comprise a plurality of layers of an organic dielectric material, such as prepreg or polyimide, with conductive traces 114 between layers (not shown) or adjacent to layers, such as on the top surface (or bottom surface) of package substrate 104. In the figure, conductive traces 114 shown are bond pads merely for ease of illustration; they may also comprise wiring, fiduciary marks, thermal pads, via landing pads etc. Channel 120 is provisioned in core 108 in any suitable pathway, shape, form, dimensions, etc. for appropriate heat transfer operations suitable for the amount of heat generated by IC die 102 in microelectronic assembly 100. Channel 120 may be configured around conductive through-holes 118 in some embodiments; in other embodiments, conductive through-holes 118 and conductive traces 114 as appropriate may be provisioned around channel 120 so as not to interfere therewith.

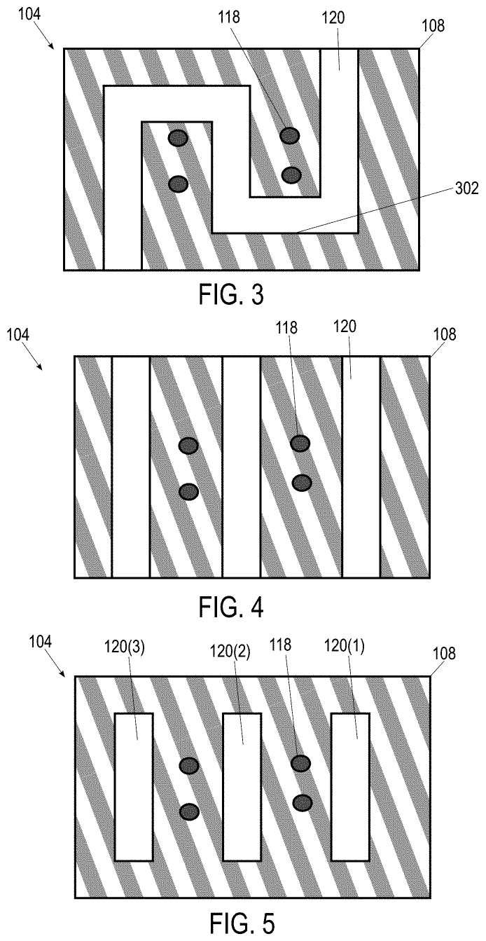

FIG. 3 is a top-view of a portion of an example channel 120 in a microelectronic assembly according to some embodiments of the present disclosure. Channel 120 may comprise one or more turns (e.g., U-turns) 302 in core 108. In the figure, two turns 302 are shown. Any number of turns 302 may be provisioned in channel 120 within the broad scope of the embodiments. In this and subsequent figures showing example forms of channel 120, vias 118 are shown merely for illustrative purposes. In some embodiments, vias 118 may be absent proximate to channel 120; in other embodiments, vias 118 may be located independent of channel 120, for example, based on electrical routing requirements and channel 120 appropriately disposed around vias 118. In other embodiments, the number and density of placement of vias 118 between bends of channel 120 may vary with spacing and electrical requirements stemming from other considerations such as manufacturing and electrical functionality.

FIG. 4 is a top-view of a portion of another example channel 120 in a microelectronic assembly according to some embodiments of the present disclosure. In some embodiments, channel 120 may comprise straight parallel pathways that may be separate channels through which different coolant flows. In other embodiments, channel 120 may comprise straight parallel pathways that may be connected to a single source of coolant.

FIG. 5 is a top-view of a portion of yet another example channel 120 in a microelectronic assembly according to some embodiments of the present disclosure. Three separate channels 120, namely 120(1), 120(2) and 120(3) are shown in the figure merely as examples and for ease of illustration and not as limitations. Any number of separate channels 120 may be included in core 108 within the broad scope of the embodiments. Channels 120(1)-120(3) may be sealed channels, the coolants within unconnected to each other or to any external cooling circuit (i.e., external to package substrate 104).

FIG. 6 is a top-view of a portion of yet another example channel in a microelectronic assembly according to some embodiments of the present disclosure. Channel 120 may be configured such that a portion 120A of channel 120 may cross another portion 120B of channel 120. In the example embodiment shown, portions 120A and 120B are mutually orthogonal; in other embodiments, portions 120A and 120B may cross each other at other angles within the broad scope of the embodiments.

FIG. 7 is a top-view of a portion of yet another example channel in a microelectronic assembly according to some embodiments of the present disclosure. Channel 120 may comprise forked portions, for example, with a plurality of forks in a region of core 108 where faster heat transfer is desired (e.g., at evaporator 122 or condenser 124). In the example embodiment shown in the figure, channel 120 is split into three forks, namely portions 120A, 1206, and 120C. Any number of forks may be provisioned in channel 120 within the broad scope of the embodiments. Further the embodiment in the figure shows a forked end (e.g., terminating at the forks); in other embodiments, for example, in a closed loop configuration, the forks may recombine further along in channel 120.

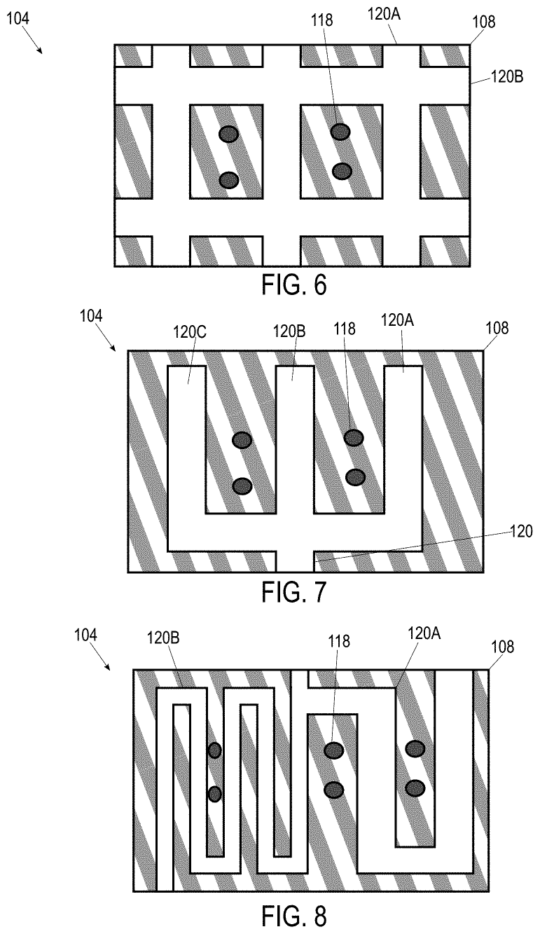

FIG. 8 is a top-view of a portion of yet another example channel in a microelectronic assembly according to some embodiments of the present disclosure. Channel 120 may comprise variable sizes along its length in core 108. For example, a portion 120A of channel 120 may be wider than another portion 120B. In some embodiments, some portions (e.g., 120B) may be more closely packed (e.g., with a greater number of turns per square micrometers) than other portions (e.g., 120A).

FIG. 9 is a top-view of a portion of yet another example channel in a microelectronic assembly according to some embodiments of the present disclosure. In some embodiments, core 108 may comprise more than one channel 120. In the example embodiment shown, two separate channels 120(1) and 120(2) are shown merely for ease of illustration and not as a limitation. Any number of channels may be provisioned in core 108 within the broad scope of the embodiments. Some channels (e.g., 120(1)) of the plurality of channels may be less densely packed than other channels (e.g., 120(2)). Some channels (e.g., 120(1)) may be wider than other channels (e.g., 120(2)). Some channels may be straight, and other channels curved or with multiple turns. Some channels may be sealed and other channels may be straight.

FIG. 10 is a top-view of a portion of yet another example channel in a microelectronic assembly according to some embodiments of the present disclosure. In some embodiments, core 108 may comprise more than one channel 120. In the example embodiment shown, two separate channels 120(1) and 120(2) are shown merely for ease of illustration and not as a limitation. Any number of channels may be provisioned in core 108 within the broad scope of the embodiments. Some channels (e.g., 120(1)) may be arranged in a closed loop, i.e., joined end to end within core 108. Some other channels (e.g., 120(2)) may be arranged in an open loop, i.e., coupled to an external cooling circuit or not joined end to end.

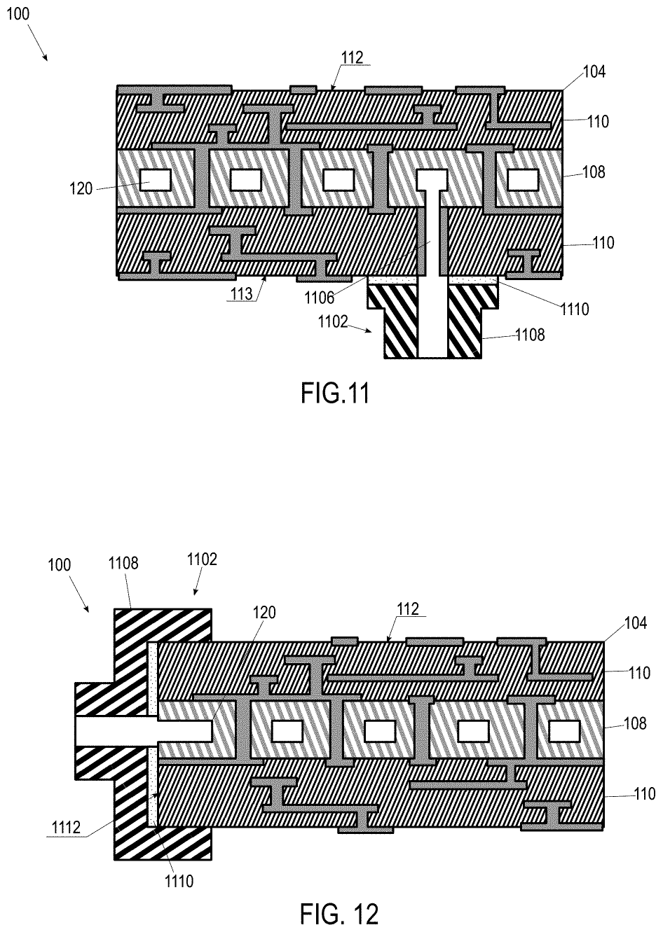

FIG. 11 is a simplified cross-sectional view of another example microelectronic assembly according to some embodiments of the present disclosure. In some embodiments, channel 120 may be coupled to an external cooling circuit 1102 by one or more thermal vias 1106. Note that thermal vias 1106 may comprise hollow vias similar to channel 120 (as shown in the figure), and also filled vias (not shown), for example, filled with thermally conductive material, such as copper. In the example embodiment shown, thermal vias 1106 comprise open channels orthogonal to channel 120 through which the coolant can flow into external cooling circuit 1102. In some embodiments, external cooling circuit 1102 may be coupled to package substrate 104 on surface 113 opposite to surface 112 where IC die 102 is attached by a clamp 1108. In other embodiments, external cooling circuit 1102 may be coupled to package substrate 104 on surface 112. Clamp 1108 may have increased area (e.g., flange) at the area of contact with surface 113. A gasket 1110 between clamp 1108 and surface 113 may prevent leakage of the coolant. In some embodiments, gasket 1110 may comprise a removable O-ring made of an elastomeric material (e.g., rubber, silicone). In other embodiments, gasket 1110 may comprise an adhesive. Other fastening means (e.g., screws, bolts, etc.) may also be used to attach external cooling circuit 1102 to package substrate 104.

FIG. 12 is a simplified cross-sectional view of yet another example microelectronic assembly according to some embodiments of the present disclosure. In some embodiments, external cooling circuit 1102 may be coupled to package substrate 104 on a side 1112 orthogonal to surface 112, for example, in direct contact with core 108. This side-mount makes it possible to access channel 120 without an intermediate thermal via 1106 through redistribution layers 110. In the example embodiment shown, clamp 1108 contacts surface 112 and surface 113 of package substrate 104 so that side 1112 of package substrate 104 is held within clamp 1108. In some embodiments, portions of side 1112 proximate to the openings for channel 120 may be enclosed by clamp 1108. Other fastening means and configurations can also be used within the broad scope of the embodiments. Gasket 1110 prevents leakage of coolant at the junction of external cooling circuit 1102 with package substrate 104.

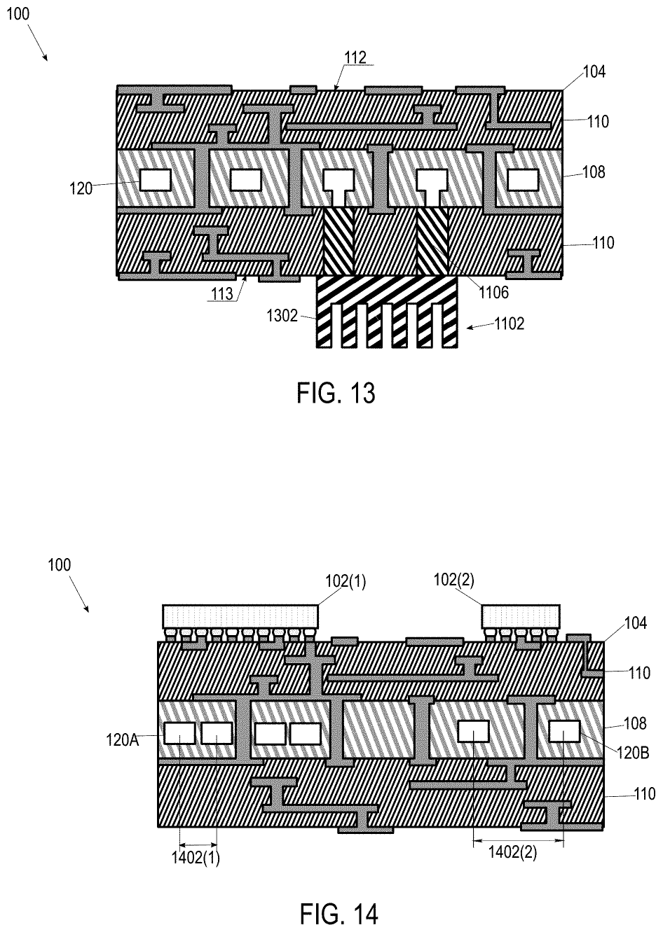

FIG. 13 is a simplified cross-sectional view of yet another example microelectronic assembly according to some embodiments of the present disclosure. In the example embodiment shown, external cooling circuit 1102 comprises a heat sink 1302. Thermal vias 1106 provide a conduction pathway for heat from channel 120 to heat sink 1302. Thermal via 1106 may comprise a through-hole through redistribution layers 110, filled with a thermally conductive material. In some embodiments, the thermally conductive material may comprise the same material as used for conductive traces 114 and/or conductive vias 116. In other embodiments, the thermally conductive material may comprise the same material as heat sink 1302. In some embodiments (e.g., as shown), channel 120 may be shaped with openings through core 108 so that the coolant is in contact with thermal vias 1106 for direct heat transfer from the coolant to thermal vias 1106. In other embodiments (not shown), thermal vias 1106 may extend through core 108 to contact channel 120 for direct heat transfer from the coolant to thermal vias 1106. In yet other embodiments, neither channel 120 nor thermal vias 1106 may neither extend through core 108, and heat transfer may be by conduction through core 108 from the coolant to thermal vias 1106.

FIG. 14 is a simplified cross-sectional view of yet another example microelectronic assembly according to some embodiments of the present disclosure. More than one IC die 102, for example, IC dies 102(1) and 102(2) may be attached to package substrate 104. One of the IC dies, for example, IC die 102(1) may produce more heat during operation than another IC die, for example, IC die 102(2). Channel 120 may be configured in core 108 such that a portion 120A has spacing 1402(1) between adjacent turns of channel 120 under the shadow of IC die 102(1) and spacing 1402(2) between adjacent turns of channel 120 under the shadow of IC die 102(2). Spacing 1402(1) may smaller than spacing 1402(2) to accommodate the higher heat transfer density under IC die 102(1).

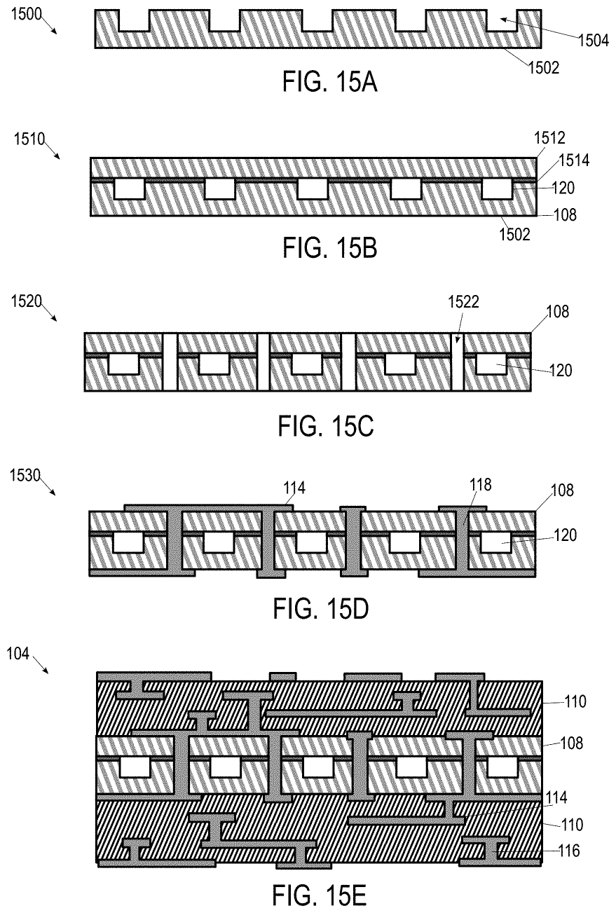

FIGS. 15A-15E are simplified cross-sectional views of various stages of manufacture of an example microelectronic assembly according to some embodiments of the present disclosure. FIG. 15A shows an assembly 1500 subsequent to processing a panel 1502 of a core material (e.g., glass, ceramic, metal) to form an open channel 1504. In embodiments where the core material is glass, open channel 1504 may be formed by selective laser-induced etching or wet etching. In embodiments where the core material is ceramic, open channel 1504 may be formed by molding channel 120 in the ceramic, for example, by electrical or electrochemical discharge machining. In embodiments where the core material is metal, open channel 1504 may be formed by etching or laser ablation.

FIG. 15B is a simplified cross-sectional view of assembly 1510 subsequent to sealing a topside of open channel 1504 with another panel 1512 comprising the core material to complete forming core 108 with closed channel 120 therein. The sealing may be performed by bonding panel 1512 over panel 1502. In some embodiments, panel 1512 may comprise the same structure as panel 1502 with open channels therethrough. A plurality of such panels with open channels may be bonded one over the other to form a multi-layered structure comprising channels 120 in multiple layers. In embodiments where the core material is glass, the bonding may be performed at a high local temperature (e.g., 400 degrees Celsius) greater than a melting point of glass to form a hermetic seal of fused glass. In embodiments where the core material is ceramic, the sealing comprises depositing glass on a surface of panels 1502 and 1512 and fusing the glass at a localized temperature greater than a melting point of the glass. In some embodiments, the sealing may be performed by suitable adhesive means. In some embodiments, for example, where channel 120 is sealed with the coolant inside, coolant may be filled in channel 120 by vacuuming the coolant into channel 120 and sealing thereafter.

FIG. 15C is a simplified cross-sectional view of assembly 1520 subsequent to forming through-holes 1522 through core 108. Through-holes 1522 may be formed by etching or drilling between turns of channel 120 (or between separate channels 120) in various embodiments.

FIG. 15D is a simplified cross-sectional view of assembly 1530 subsequent to depositing a conductive material in through-holes 1522 to form conductive vias 118 and conductive traces 114 on either side of core 108. In some embodiments, conductive vias 118 may be filled with more than one material, different from the conductive material used for conductive traces 114. In embodiments where the core material is a conductive metal, through-holes 1522 may be first covered with an insulating material and then filled with conductive metal. The insulating material may also be deposited on either side of the conductive core material before depositing conductive traces 114.

FIG. 15E is a simplified cross-sectional view subsequent to completing package substrate 104. A dielectric material of redistribution layers 110 is deposited on conductive traces 114 on either side of core 108 (e.g., assembly 1530); conductive vias 116 are formed through the dielectric material to couple to conductive traces 114. The operations of forming conductive traces 114, depositing the dielectric material, and forming conductive vias 116 may be repeated until a desired structure of redistribution layers 110 is obtained on either side of core 108. In some embodiments, the operations as described herein may be modified so that redistribution layers 110 may be completed on one side of core 108 before forming redistribution layers 110 on the other side of core 108. In yet other embodiments, the operations may be performed on one side of core 108 only, to generate an asymmetric structure of package substrate 1-4.

In various embodiments, any of the features discussed with reference to any of FIGS. 1-15 herein may be combined with any other features to form a package with one or more IC dies as described herein, for example, to form a modified microelectronic assembly 100. Some such combinations are described above, but, in various embodiments, further combinations and modifications are possible.

Example Devices and Components

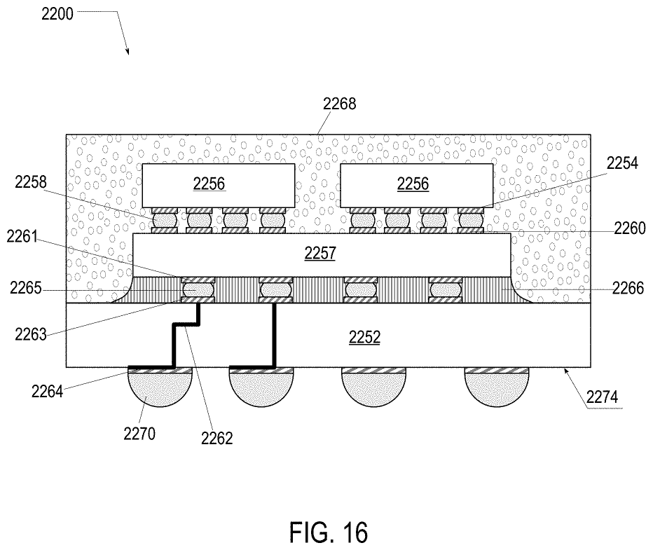

The packages disclosed herein, e.g., any of the embodiments shown in FIGS. 1-15 or any further embodiments described herein, may be included in any suitable electronic component. FIGS. 16-18 illustrate various examples of packages, assemblies, and devices that may be used with or include any of the IC packages as disclosed herein.

FIG. 16 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

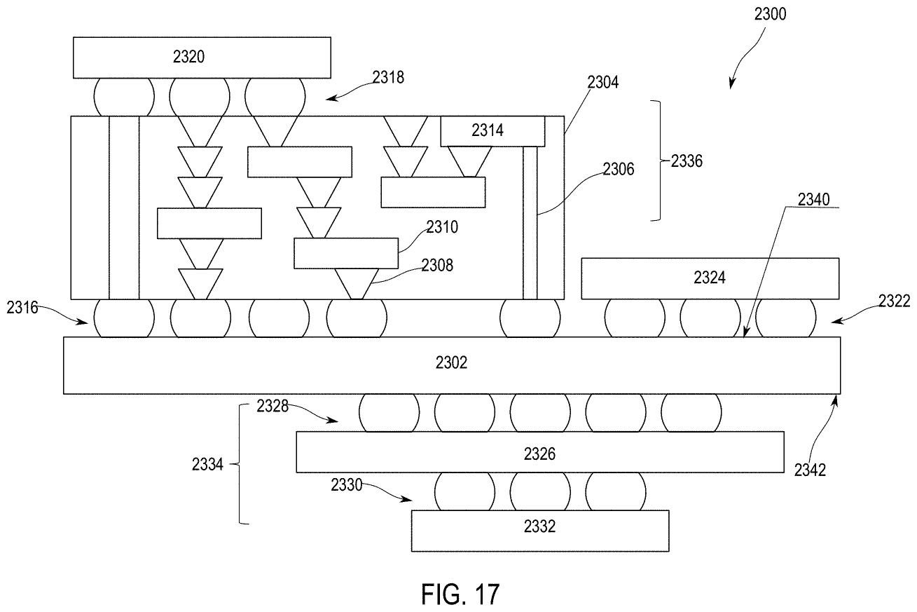

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 17.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., high-bandwidth memory), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 17 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 16.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 16. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio-frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

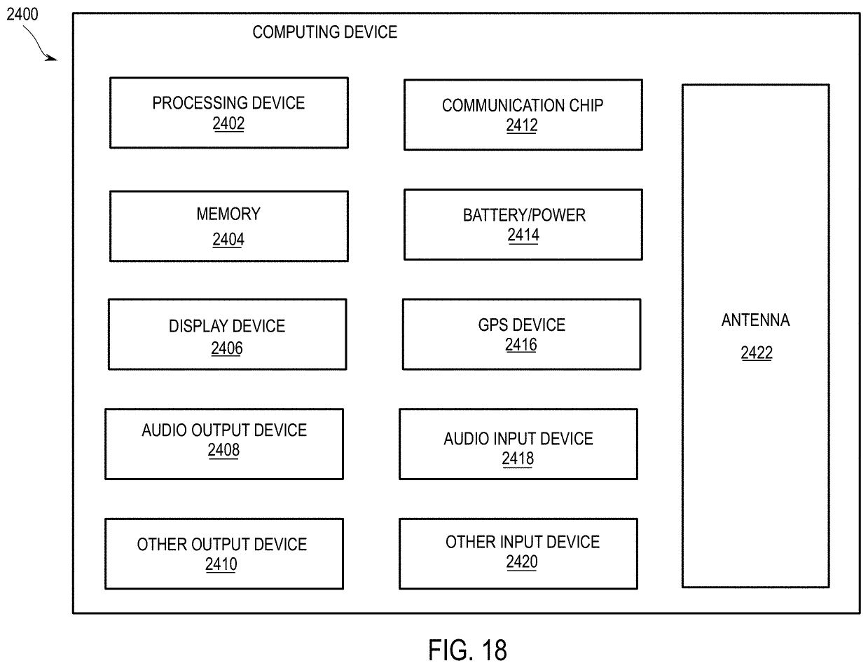

FIG. 18 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 16). In yet another example, any one or more of the components of computing device 2400 may include an IC device assembly 2300 (e.g., as shown in FIG. 17).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-chip (SOC) die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio-frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

The following paragraphs provide various examples of the embodiments disclosed herein.

Example 1 provides a microelectronic assembly (e.g., 100, FIG. 1, FIG. 2), comprising: an IC die (e.g., 102); and a package substrate (e.g., 104) comprising a core (e.g., 108) and redistribution layers (e.g., 110) on either side of the core, in which: the IC die is coupled to a surface (e.g., 112) of the package substrate, the surface being parallel to the core, the core comprises one of glass, ceramic, and metal, the redistribution layers comprise one or more layers of a dielectric material, with conductive traces (e.g., 114) adjacent to the one or more layers of the dielectric material and conductive vias (e.g., 116) through the one or more layers of the dielectric material, and the core comprises a hollow channel (e.g., 120, configured to permit flow of a coolant).

Example 2 provides the microelectronic assembly of example 1, in which the core further comprises a plurality of channels.

Example 3 provides the microelectronic assembly of example 2, in which some channels in the plurality of channels are not coplanar with other channels in the plurality of channels.

Example 4 provides the microelectronic assembly of any of examples 1-3, in which: the core further comprises conductive through-holes (e.g., 118) coupled to the conductive traces in the redistribution layers on either side of the core, and the conductive through-holes in the core are electrically insulated from each other.

Example 5 provides the microelectronic assembly of any of examples 1-4, in which the channel has a circular cross-section (e.g., FIG. 2).

Example 6 provides the microelectronic assembly of any of examples 1-4, in which the channel has a rectangular cross-section (e.g., FIG. 1).

Example 7 provides the microelectronic assembly of any of examples 1-4, in which the channel has an irregularly shaped cross-section.

Example 8 provides the microelectronic assembly of any of examples 1-7, in which the channel comprises a plurality of turns (e.g., 302) in a plane parallel to the surface of the package substrate (e.g., FIGS. 3, 8, 9, 10).

Example 9 provides the microelectronic assembly of example 8, in which the channel is joined end to end within the package substrate (e.g., FIG. 10).

Example 10 provides the microelectronic assembly of any of examples 8-9, in which a portion of the channel is looped closer together than another portion of the channel (e.g., FIG. 8).

Example 11 provides the microelectronic assembly of any of examples 8-10, in which a portion of the channel is spaced 60 micrometers apart from another portion of the channel.

Example 12 provides the microelectronic assembly of any of examples 8-11, further comprising another IC die (e.g., FIG. 14), in which: the IC die is configured to produce more heat during operation than the another IC die, and a portion of the channel proximate to the IC die is more densely packed with a greater number of turns than another portion of the channel proximate to the another IC die.

Example 13 provides the microelectronic assembly of any of examples 1-7, in which the channel is sealed within the package substrate (e.g., FIG. 5).

Example 14 provides the microelectronic assembly of any of examples 1-7, in which a portion of the channel crosses another portion of the channel in a plane parallel to the surface of the package substrate (e.g., FIG. 6).

Example 15 provides the microelectronic assembly of any of examples 1-7, in which the channel comprises forked portions in a plane parallel to the surface of the package substrate (e.g., FIG. 7).

Example 16 provides the microelectronic assembly of any of examples 1-15, in which the channel is 60 micrometers wide measured along a dimension parallel to the surface of the package substrate.

Example 17 provides the microelectronic assembly of any of examples 1-16, in which the channel is 500 micrometers wide measured along a dimension parallel to a thickness of the core.

Example 18 provides the microelectronic assembly of any of examples 1-17, in which a height of the channel is less than a thickness of the core.

Example 19 provides the microelectronic assembly of any of examples 1-18, in which a portion of the channel is wider than another portion of the channel (e.g., FIG. 8).

Example 20 provides the microelectronic assembly of any of examples 1-8, or 14-19, in which the channel is coupled to an external cooling circuit (e.g., 1102, FIGS. 11-13).

Example 21 provides the microelectronic assembly of example 20, in which the external cooling circuit is configured to force the coolant to flow in the channel.

Example 22 provides the microelectronic assembly of any of examples 20-21, in which the external cooling circuit is removably affixed to the package substrate on another surface (e.g., 1104) of the package substrate opposite to the surface (e.g., FIG. 11).

Example 23 provides the microelectronic assembly of example 22, in which a gasket (e.g., 1110) between the external cooling circuit and the package substrate is configured to prevent leakage of the coolant.

Example 24 provides the microelectronic assembly of example 20, in which the external cooling circuit is removably affixed to the package substrate by a clamp (e.g., 1108) on another surface (e.g., 1112) of the package substrate perpendicular to the surface of the package substrate (e.g., FIG. 12).

Example 25 provides the microelectronic assembly of example 24, in which a gasket (e.g., 1110) between the clamp and the package substrate is configured to prevent leakage of the coolant.

Example 26 provides the microelectronic assembly of example 20, in which the external cooling circuit comprises a heat sink (e.g., 1302, FIG. 13).

Example 27 provides the microelectronic assembly of any of examples 20-26, in which the channel is coupled to the external cooling circuit by thermal vias (e.g., 1106) in the package substrate.

Example 28 provides the microelectronic assembly of any of examples 1-27, in which coolant is in at least one of a liquid state and a gaseous state.

Example 29 provides the microelectronic assembly of example 1, in which the channel comprises one of: a SHP, a LHP, a FEHP, a MHP, and a PHP.

Example 30 provides the microelectronic assembly of any of examples 1-29, in which the package substrate is coupled to a PCB on another surface opposite to the surface.

Example 31 provides a component of a microelectronic assembly, the component comprising: a core comprising a channel with coolant; and redistribution layers on either side of the core, the redistribution layers comprising: one or more layers of a dielectric material; conductive traces adjacent to the one or more layers; and conductive vias through the one or more layers coupled to the conductive traces, in which: the core comprises one of glass, ceramic, and metal, and the coolant is one of a liquid material and a gaseous material.

Example 32 provides the component of example 31, in which the component comprises a package substrate coupled to an IC die on a surface and to a PCB on an opposing surface, the core being parallel to the surface and the opposing surface.

Example 33 provides the component of example 31, in which the component comprises a PCB coupled to a package substrate on a surface parallel to the core.

Example 34 provides the component of any of examples 31-33, in which the channel comprises a plurality of turns in a plane of the core.

Example 35 provides the component of example 34, in which the channel is joined end to end within the component.

Example 36 provides the component of example 34, in which a portion of the channel is looped more densely together than another portion of the channel.

Example 37 provides the component of any of examples 31-36, in which the channel has a circular cross-section.

Example 38 provides the component of any of examples 31-36, in which the channel has a rectangular cross-section.

Example 39 provides the component of any of examples 31-36, in which the channel has an irregularly shaped cross-section.

Example 40 provides the component of any of examples 31-39, in which a height of the channel is less than a thickness of the core.

Example 41 provides the component of any of examples 31-40, in which a portion of the channel is wider than another portion of the channel.

Example 42 provides the component of any of examples 31-41, in which a portion of the channel is not coplanar with another portion of the channel.

Example 43 provides the component of any of examples 31-42, in which the channel is sealed within the core.

Example 44 provides the component of any of examples 31-42, in which a portion of the channel crosses another portion of the channel.

Example 45 provides the component of any of examples 31-42, in which the channel comprises forked portions.

Example 46 provides the component of any of examples 31-42, in which the channel is coupled to an external cooling circuit.

Example 47 provides the component of example 46, further comprising thermal vias coupled to the channel, in which the thermal vias extend through the redistribution layers on any one side of the core and couple to the external cooling circuit.

Example 48 provides the component of example 47, in which the thermal vias are arranged in an array.

Example 49 provides the component of any of examples 46-48, in which the external cooling circuit is configured to force the coolant through the channel.

Example 50 provides the component of example 46, in which the external cooling circuit comprises a heat sink.

Example 51 provides a method of forming a component in a microelectronic assembly, the method comprising (e.g., FIGS. 15A-15E): providing a panel (e.g., 1502) of a core material comprising one of glass, ceramic, and metal (e.g., FIG. 15A); forming an open channel (e.g., 1504) in the core material; sealing a topside of the open channel with another panel (e.g., 1512) comprising the core material to complete forming a core with a closed channel (e.g., 120) therein (e.g., FIG. 15B); forming through-holes (e.g., 1522) in the core through a thickness of the core (e.g., FIG. 15C); depositing a conductive material in the through-holes (e.g., FIG. 15D); forming conductive traces (e.g., 114) on either side of the core (e.g., FIG. 15D); depositing a dielectric material on the conductive traces on either side of the core; forming conductive vias through the dielectric material to couple to the conductive traces; and repeating forming the conductive traces, depositing the dielectric material, and forming the conductive vias until a desired structure of redistribution layers is obtained on either side of the core (e.g., FIG. 15E).

Example 52 provides the method of example 51, in which the core material comprises glass, and forming the open channel comprises etching the channel in the glass.

53 provides the method of example 52, in which the etching comprises one of selective laser-induced etching and wet etching.

54 provides the method of any of examples 52-53, in which sealing the topside comprises fusing the another panel to the panel at a temperature greater than a melting point of the glass.

Example 55 provides the method of example 51, in which the core material comprises ceramic, and forming the open channel comprises molding the channel in the ceramic.

Example 56 provides the method of example 55, in which molding the channel comprises electric or electrochemical discharge machining.

Example 57 provides the method of any of examples 55-56, in which sealing the topside comprises: depositing glass on a surface of the panel and the another panel; and fusing the another panel to the panel at a temperature greater than a melting point of the glass.

Example 58 provides the method of example 51, in which the core material comprises metal, and forming the open channel comprises etching or laser ablating the channel in the metal.

Example 59 provides the method of any of examples 51-58, further comprising repeating the forming an open channel in the core material and sealing a topside of the open channel with another panel to form a plurality of layers of non-coplanar channels.

Example 60 provides the method of any of examples 51-59, further comprising filling the channel with a coolant.

Example 61 provides the method of any of examples 51-60, in which forming through-holes in the core comprises etching or drilling through the core.

Example 62 provides the method of any of examples 51-61, in which the redistribution layers on one side of the core are completed before forming the redistribution layers on an opposing side of the core.

Example 63 provides the method of any of examples 51-62, further comprising coupling an external cooling circuit to the channel.

Example 64 provides the method of example 63, in which coupling the external cooling circuit comprises surface mounting the cooling circuit on a surface of the component parallel to the core.

Example 65 provides the method of example 63, in which coupling the external cooling circuit comprises side mounting the cooling circuit on a surface of the component orthogonal to the core.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
an integrated circuit (IC) die; and
a package substrate comprising a core and redistribution layers on either side of the core,
wherein:
the IC die is coupled to a surface of the package substrate, the surface being parallel to the core,
the core comprises one of glass, ceramic, and metal,
the redistribution layers comprise one or more layers of a dielectric material, with conductive traces adjacent to the one or more layers of the dielectric material and conductive vias through the one or more layers of the dielectric material, and
the core comprises a hollow channel.

2. The microelectronic assembly of claim 1, wherein the channel comprises a plurality of turns in a plane parallel to the surface of the package substrate.

3. The microelectronic assembly of claim 2, wherein the channel is joined end to end within the package substrate.

4. The microelectronic assembly of claim 2, further comprising another IC die, wherein:
the IC die is configured to produce more heat during operation than the another IC die, and
a portion of the channel proximate to the IC die is more densely packed with a greater number of turns than another portion of the channel proximate to the another IC die.

5. The microelectronic assembly of claim 1, wherein the channel is sealed within the package substrate.

6. The microelectronic assembly of claim 1, wherein a portion of the channel crosses another portion of the channel in a plane parallel to the surface of the package substrate.

7. The microelectronic assembly of claim 1, wherein the channel comprises forked portions in a plane parallel to the surface of the package substrate.

8. The microelectronic assembly of claim 1, wherein the channel is coupled to an external cooling circuit.

9. The microelectronic assembly of claim 8, wherein the external cooling circuit comprises a heat sink.

10. A component of a microelectronic assembly, the component comprising:
a core comprising a channel with coolant; and
redistribution layers on either side of the core, the redistribution layers comprising:
one or more layers of a dielectric material;
conductive traces adjacent to the one or more layers; and
conductive vias through the one or more layers coupled to the conductive traces,
wherein:
the core comprises one of glass, ceramic, and metal, and
the coolant is one of a liquid material and a gaseous material.

11. The component of claim 10, wherein the component comprises a package substrate coupled to an IC die on a surface and to a PCB on an opposing surface, the core being parallel to the surface and the opposing surface.

12. The component of claim 10, wherein the component comprises a PCB coupled to a package substrate on a surface parallel to the core.

13. The component of claim 10, wherein the channel comprises a plurality of turns in a plane of the core.

14. The component of claim 10, wherein the channel is sealed within the core.

15. The component of claim 10, wherein a portion of the channel crosses another portion of the channel.

16. The component of claim 10, wherein the channel is coupled to an external cooling circuit.

17. A method of forming a component in a microelectronic assembly, the method comprising:
providing a panel of a core material comprising one of glass, ceramic, and metal;
forming an open channel in the core material;
sealing a topside of the open channel with another panel comprising the core material to complete forming a core with a closed channel therein;
forming through-holes in the core through a thickness of the core;
depositing a conductive material in the through-holes;
forming conductive traces on either side of the core;
depositing a dielectric material on the conductive traces on either side of the core;
forming conductive vias through the dielectric material to couple to the conductive traces; and
repeating forming the conductive traces, depositing the dielectric material, and forming the conductive vias until a desired structure of redistribution layers is obtained on either side of the core.

18. The method of claim 17, wherein the core material comprises glass, and forming the open channel comprises etching the channel in the glass.

19. The method of claim 17, wherein the core material comprises ceramic, and forming the open channel comprises molding the channel in the ceramic.

20. The method of claim 17, further comprising coupling an external cooling circuit to the channel.
